(19) United States
(12) Patent Application Publication
(10) Pub. No.: US 2003/0176055 A1
(43) Pub. Date: Sep. 18, 2003

(54) Method and structure for reducing capacitance between interconnect lines

(75) Inventor: Bing-Chang Wu, Shu-Lin Chen (TW)

Correspondence Address: POWELL, GOLDSTEIN, FRAZER & MURPHY LLP, P.O. BOX 97223, WASHINGTON, DC, 20090-7223, US

(73) Assignee: United Microelectronics Corp.

(21) Appl. No.: 10/386,537

(22) Filed: Mar. 13, 2003

Related U.S. Application Data
(62) Division of application No. 09/624,321, filed on Jul. 24, 2000, now abandoned.

(51) Int. Cl. H01L 21/4763; H01L 23/48

(52) U.S. Cl. 438/618; 257/734

(57) ABSTRACT

A method and structure for reducing capacitance between interconnect lines, characterized in that a pad oxide layer is added on each of metal lines over a substrate, having a plurality of semiconductor elements and one dielectric layer for isolating the semiconductor elements formed thereon, to form an interconnect line. The pad oxide layer added on each of metal lines increases intra-metal aspect ratio and facilitates air gap formation in each of the spacings between the adjacent interconnect lines having larger aspect ratios. Moreover, each of air gaps is formed below the pad oxide layer, while the top end and lower end thereof respectively exceed the top end and bottom end of the adjacent metal lines. The distance from the portion of the air gap between the top end and bottom end of the adjacent metal lines to the sidewall of the adjacent metal lines is more consistent and smaller. Therefore, a better low K effect between the adjacent metal lines is obtained.

### BACKGROUND OF THE INVENTION

1. Field of the Invention

The present invention relates to a method of fabricating an interconnect structure, and more particularly relates to a method of reducing capacitance between interconnect lines and a structure thereof.

2. Description of the Prior Art

Integrated circuits have continued to shrink in size and increase in complexity with each new generation of devices. As a result, integrated circuits increasingly require very close spacing of interconnect lines and many now require multiple levels of metalization, to interconnect the various circuits on the device. Since closer spacing increases capacitance between adjacent lines, as the device geometries shrink and densities increase capacitance, cross talk between adjacent lines becomes more of a problem. Therefore, it becomes increasingly more desirable to use lower dielectric materials to offset this trend and thereby lower capacitance between closely spaced interconnects.

Interconnect capacitance has two components: the line-to-substrate, or line-to-ground capacitance and line-to-line capacitance. For ultra large scale integration at 0.25 μm design rule and beyond, performance is dominated by interconnect RC delay, with line-to-line capacitance being the dominated contributor to total capacitance. Therefore, a reduction of the line-to-line capacitance alone will provide a dramatic reduction in total capacitance. It becomes increasingly important to implement low K materials between tightly spaced metal lines.

The inter-metal dielectric (IMD) of the prior art is typically SiO₂ which has a dielectric constant of about 4.0. It would be desirable to replace this material with a material having a lower dielectric constant. However, there are many issues existing in the technique of employing low K materials between tightly spaced metal lines, such as mechanical strength, dimensional stability, thermal stability, ease of pattern and etch, thermal conductivity, CMP compatibility and complexity of integration. Many low K materials including polysilsequioxane, parylene, polyimide, benzocyclobutene and amorphous TELFLON all have the above problems, and are inferior to the currently used inter-metal dielectric material SiO₂.

Thus, currently, the most appropriate method to implement low K materials between tightly spaced interconnect lines is utilizing air gaps between interconnect lines. The air gap formation permits the utilization of air as an intra-level dielectric material, which has the relative dielectric constant of 1.0, which is much lower than the relative dielectric constants of other conventional dielectric materials. However, as shown in the drawing of FIG. 1, the conventional process for forming air gaps in the substrate, having interconnect lines formed thereon, includes depositing an inter-metal dielectric layer 2 over the substrate 1 to form air gaps 3, 4 between the interconnect lines. Due to the spacing between interconnect lines is varied, the spacing is larger, the air gap is formed higher from the substrate 1, such as air gap 4. When subsequently proceeding CMP process for the inter-metal dielectric layer 2, the higher air gap 4 is open up by the CMP process, then such as acid, Alumina will enter into the inter-metal dielectric layer 2 to result in this layer works fail. Moreover, the air gap is formed faster near the lateral wall of the bottom of interconnect lines, the hole of the air gap is tapered from the bottom to the top of the air gap. Thus, the low K effect of the conventional air gap is not well.

Accordingly, it is desired to find out a method for forming air gaps between interconnect lines, to not only reduce capacitance between the interconnect lines, but also overcome the drawbacks of the conventional air gap formation process.

### SUMMARY OF THE INVENTION

The primary object of the invention is to provide a method for reducing capacitance between interconnect lines, which forming a pad oxide layer on each of metal lines to form an interconnect line, thereby increase intra-metal aspect ratio to facilitate air gap formation in the spacing between adjacent interconnect lines.

Another object of the invention is to provide a method for reducing capacitance between interconnect lines, which forms a more ideal air gap in the spacing between adjacent metal lines, the upper and lower ends of the air gap respectively exceeding the top and bottom ends of the adjacent metal lines, and the distance from the portion of air gap between the top and bottom ends of the metal line to the sidewall of the metal line is more consistent and smaller, so as to minimize difference of low K effect of the portion of air gap, and give better low K effect.

A further object of the invention is to provide a method for reducing capacitance between interconnect lines, which forms a pad oxide layer on each of metal lines to form an interconnect line, so that an air gap is formed in the spacing between the adjacent interconnect lines under the top end of the pad oxide layer. Therefore, the air gap is not damaged while proceeding subsequent CMP process.

A still further object of the present invention is to provide an interconnect structure for reducing capacitance between interconnect lines, which is characterized in that each of air gaps in the spacings of adjacent interconnect lines each of which comprising a lower metal line and a upper pad oxide layer is formed below the top end of the pad oxide layer with more consistent and smaller spacing between the air gap and the sidewall of the metal line.

In order to achieve the above objects of this invention, the present invention provides a method and structure for reducing capacitance between interconnect lines comprising: providing a substrate having a plurality of semiconductor elements and one dielectric layer for isolating the semiconductor elements formed thereon. Forming a metal layer over the substrate; and then forming a pad oxide layer over the metal layer. Subsequently, patterning and etching the metal layer and pad oxide layer to constitute interconnect lines over the substrate. Thereafter, forming an inter-metal dielectric layer over the substrate having the interconnect lines. Thereby, a plurality of air gaps are respectively formed in the spacings between the adjacent interconnect lines, having larger aspect ratios. Finally, planarizng the inter-metal dielectric layer by chemical mechanical polishing method.

### BRIEF DESCRIPTION OF THE DRAWINGS

The invention itself, however, as well as features and advantages thereof, will be best understood by reference to the detailed description of one embodiment which follows, read in conjunction with the accompanying drawings, wherein:

FIG. 1 shows a cross-sectional view of air gaps formed in the spacing between the adjacent interconnect lines in the prior art;

FIG. 2 shows a cross-sectional view of a substrate having a metal layer and a pad oxide layer sequentially formed thereon, for one embodiment of the present invention;

FIG. 3 shows a cross-sectional view of the substrate of FIG. 2, wherein interconnect lines have constituted thereon; and

FIG. 4 is a cross-sectional view of depositing an inter-metal dielectric layer over the structure of FIG. 3, in which a plurality of air gaps are respectively formed in each of the spacings between the adjacent interconnect lines having larger aspect ratios.

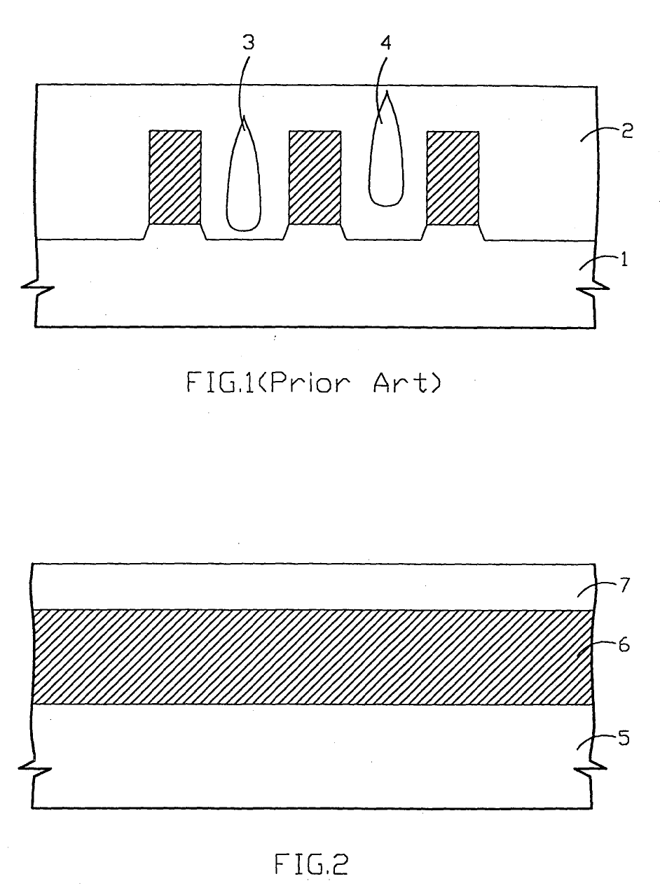

### DESCRIPTION OF THE EMBODIMENT

Referring to FIG. 2, the present invention firstly providing a substrate 5, having a plurality of semiconductor elements and one dielectric layer for isolating the semiconductor elements formed thereon (not shown in the figure); depositing a metal layer 6 over the substrate 5, the metal layer 6 can be an aluminum layer deposited by DC sputtering deposition method, about 3000˜10000 angstronm thickness, the metal layer 6 also can be formed by metals selected from the group consisting of Cu, Ta, Au, Pb, Si, W and Sn; then depositing a pad oxide layer 7 over the metal layer 6 with thickness between about 2000 angstronm and about 5000 angstronm, the pad oxide layer 7 can be a SiO₂ layer, deposited by atmospheric pressure CVD method, utilizing SiH₄ as reaction gas, under the pressure of 0.5˜1 torr, at temperature of 400˜500° C. Alternatively, deposited by plasma enhanced CVD method, utilizing SiH₄ as reaction gas, under the pressure of 1˜10 torr, at temperature of 300˜400° C. Otherwise, deposited by plasma enhanced CVD method, utilizing TEOS/O3 as reaction gas.

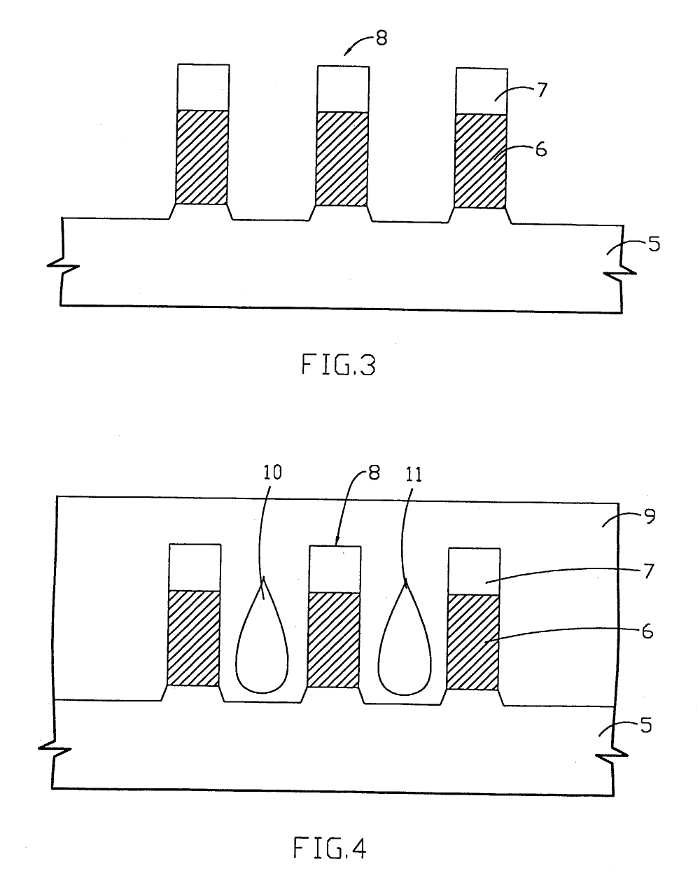

Referring to FIG. 3, subsequently, patterning and etching the pad oxide layer 7 and metal layer 6 by the conventional lithography and etching technique to constitute adjacent interconnect lines 8.

Referring to FIG. 4, thereafter, depositing an inter-metal dielectric layer 9 over the substrate 5 having adjacent interconnect lines 8 formed thereon. Since the pad oxide layer 7 formed on each of metal lines 6 increases intra-metal aspect ratio between the adjacent interconnect lines 8, a plurality of air gaps, such as air gaps 10, 11, are respectively formed in each of the spacings between the adjacent interconnect lines 8 having larger aspect ratios. Furthermore, as shown in FIG. 4, the distance from the portion of the air gaps 10 and 11 between the top end and bottom end of the metal line 6 to the respective sidewall of the metal lines 6 is more consistent and smaller. Hence, the difference of low K effect in the spacing between the adjacent metal lines 6 is minimized, and a better low K effect is obtained.

The inter-metal dielectric layer 9 formed over the substrate 5 can be a SiO₂ layer, deposited by plasma enhanced CVD method, utilizing TEOS/O₃ as reaction gas. Besides, the inter-metal dielectric layer 9 can also be a BPSG layer, deposited by atmospheric pressure CVD method, utilizing TEOS/O₃, TMPO (tri-methyl-phosphate) and TEB (tri-methyl-borate) as reaction gas, at the temperature less than 550° C. Otherwise, the BPSG layer can be formed by plasma enhanced CVD method, utilizing TEOS, O₃/O₂, TMP and TMB as reaction gas, at temperature between about 400° C. and about 500° C. However, the content of Boron is controlled in about 1˜4 weight %, while the content of Phosphorus is controlled in about 6˜8 weight %. Finally, the inter-metal dielectric layer 9 is planarized by chemical mechanical polishing method (CMP), to build up another level of metalization.

To sum up the foregoing, the present invention provides a method for air gap formation that a pad oxide layer is formed on each of metal lines to form interconnect lines having increasing aspect ratios. Thereby, a more ideal air gap is formed in the spacing between the adjacent interconnect lines, in which the portion of air gap between the top end and bottom end of the metal lines is more uniformly formed than that formed by the conventional air gap formation process. Therefore, the present invention provides better low K effect in the spacing between the adjacent metal lines. Additionally, the air gap is formed between the adjacent interconnect lines under the top end of the pad oxide layer, so that subsequent CMP process does not open up the air gap.

In accordance with the present invention, it is apparent that there has been provided an improved method of reducing capacitance between adjacent interconnect lines which overcomes the disadvantages of the prior art. The present invention is inexpensive and uncomplicated, can easily be integrated into conventional process flows without significantly increasing cycle time, maintains heat transfer efficiency through the interconnect structure, and is compatible with reducing the size of semiconductor integrated circuits.

Although one specific embodiment has been illustrated and described, it will be obvious to those skilled in the art that various modifications may be made without departing from what is intended to be limited solely by the appended claims.

What is claimed is:

1. A method for reducing capacitance between interconnect lines, the method comprising:
providing a substrate having a plurality of semiconductor elements and one dielectric layer for isolating the semiconductor elements formed thereon;
forming a metal layer over said substrate;
forming a pad oxide layer over said metal layer;
pattering and etching said pad oxide layer and metal layer to constitute said interconnect lines over said substrate;
forming an inter-metal dielectric layer over said substrate having said interconnect lines formed thereon, wherein at least an air gap is formed in a spacing between the adjacent interconnect lines; and
planarizing said inter-metal dielectric layer.

2. The method according to claim 1, wherein said metal layer is formed from materials selected from the group consisting of Al, Cu, Ta, W, Si, Au, Pb and Sn.

3. The method according to claim 1, wherein the thickness of said pad oxide layer is between about 2000 angstronm and about 5000 angstronm.

4. The method according to claim 1, wherein said pad oxide layer comprises SiO₂, deposited by atmospheric pressure CVD method.

5. The method according to claim 1, wherein said pad oxide layer comprises SiO₂, deposited by plasma enhanced CVD method.

6. The method according to claim 1, wherein said inter-metal dielectric layer comprises a SiO₂ layer, deposited by plasma enhanced CVD method, utilizing TEOS/O₃ as reaction gas.

7. The method according to claim 1, wherein said inter-metal dielectric layer comprises a BPSG layer, deposited by atmospheric pressure CVD method, utilizing TEOS/O₃, TMPO and TEB as reaction gas, at temperature lower than 550° C.

8. The method according to claim 1, wherein said inter-metal dielectric layer comprises a BPSG layer, deposited by plasma enhanced CVD method, utilizing TEOS, O₃/O₂, TMP and TMB as reaction gas, at temperature between about 400° C. and 500° C.

9. An interconnect structure, the structure comprising:
a substrate having a plurality of semiconductor elements and one dielectric layer for isolating the semiconductor elements formed thereon;
a plurality of adjacent interconnect lines having spacings therebetween with different aspect ratios with at least an air gap formed therein formed over said substrate, each of which comprising a lower metal line and a top pad oxide layer, said air gap is positioned below said pad oxide layer and the level of the top end of said air gap is beyond the upper ends of said adjacent metal lines, and the level of the lower end of said air gap is below the bottom ends of said adjacent metal lines; and
an inter-metal dielectric layer formed over said substrate having said adjacent interconnect lines formed thereon.
